(19) United States
(12) Patent Application Publication
(10) Pub. No.: US 2014/0338858 A1
(43) Pub. Date: Nov. 20, 2014

(54) FAN MODULE AND BASE SEAT THEREOF

(71) Applicant: HON HAI PRECISION INDUSTRY CO., LTD., New Taipei (TW)

(72) Inventors: SHIEN-CHENG KUO, New Taipei (TW); MI-CHIEN CHEN, New Taipei (TW)

(73) Assignee: HON HAI PRECISION INDUSTRY CO., LTD., New Taipei (TW)

(21) Appl. No.: 14/277,032

(22) Filed: May 13, 2014

(30) Foreign Application Priority Data
May 14, 2013 (CN) 2013101767459

(51) Int. Cl. H05K 7/20

(52) U.S. Cl. CPC H05K 7/20154
USPC 165/67; 165/121

(57) ABSTRACT

A fan module employed in an electronic device includes a base seat, a fan, a heat conducting tube and a covering plate. The base seat is made of polymer thermal conductive materials, and includes a bottom plate and a “U” shaped sidewall. The bottom plate includes a receiving portion and a heat sink portion. The sidewall surrounds the receiving portion to form a mounting groove and surrounds opposite sides of the heat sink portion to form a heat dissipation opening communicating with the mounting groove. The fan is rotatably mounted on the receiving portion and is received in the mounting groove. The heat conducting tube is embedded to a side of the base seat opposite to the fan. The covering plate is secured to the sidewall and covering the fan. The present disclosure further provides a base seat of the fan module.

### FIELD

The present disclosure generally relates to fan module and base seat for the fan module, and more particularly to a fan module employed in an electronic device and a base seat of the fan module.

### BACKGROUND

A traditional notebook computer is equipped with a fan module to cool components of the notebook computer. The fan module includes a base seat, a plurality of cooling fins on a top of the base seat, a heat conducting tube on a bottom of the base seat, a fan, and a case. The fan is assembled to the base seat adjacent to the plurality of cooling fins, the case is secured to the base seat and covers the fan. The fan blows air toward the cooling fins, thereby drawing heat away from the cooling fins.

### BRIEF DESCRIPTION OF THE DRAWING

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows an assembled, isometric view of a first embodiment of a fan module, the fan includes a base seat.

FIG. 2 is an exploded, isometric view of the fan module of FIG. 1.

FIG. 3 is similar to FIG. 2, but viewed from another aspect.

FIG. 4 shows an isometric view of the base seat of the fan module of FIG. 1.

FIG. 5 is similar to FIG. 4, but viewed from another aspect.

### DETAILED DESCRIPTION

The term “coupled” is defined as connected, whether directly or indirectly through intervening components, and is not necessarily limited to physical connections. The connection can be such that the objects are permanently connected or releasably connected.

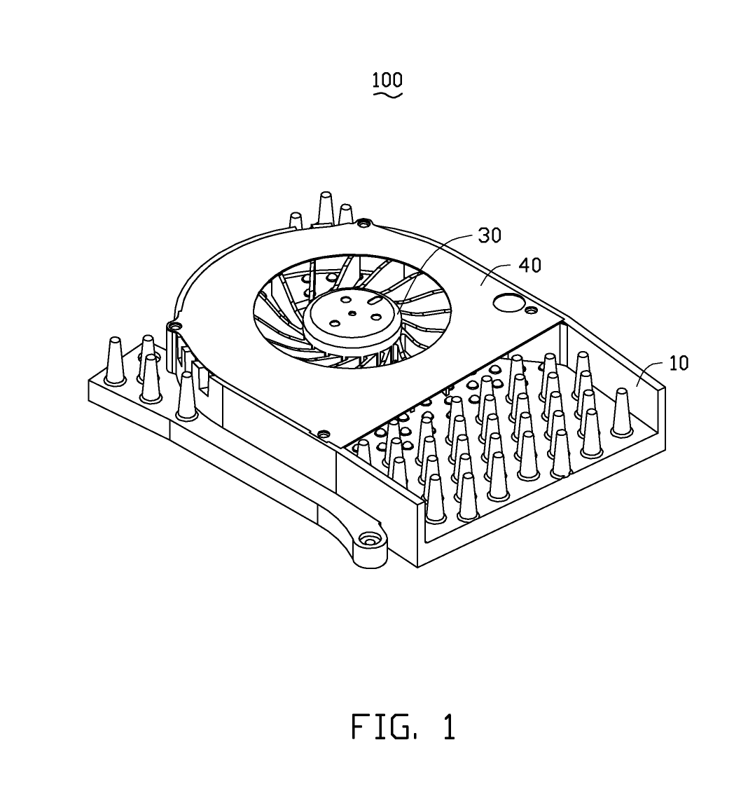

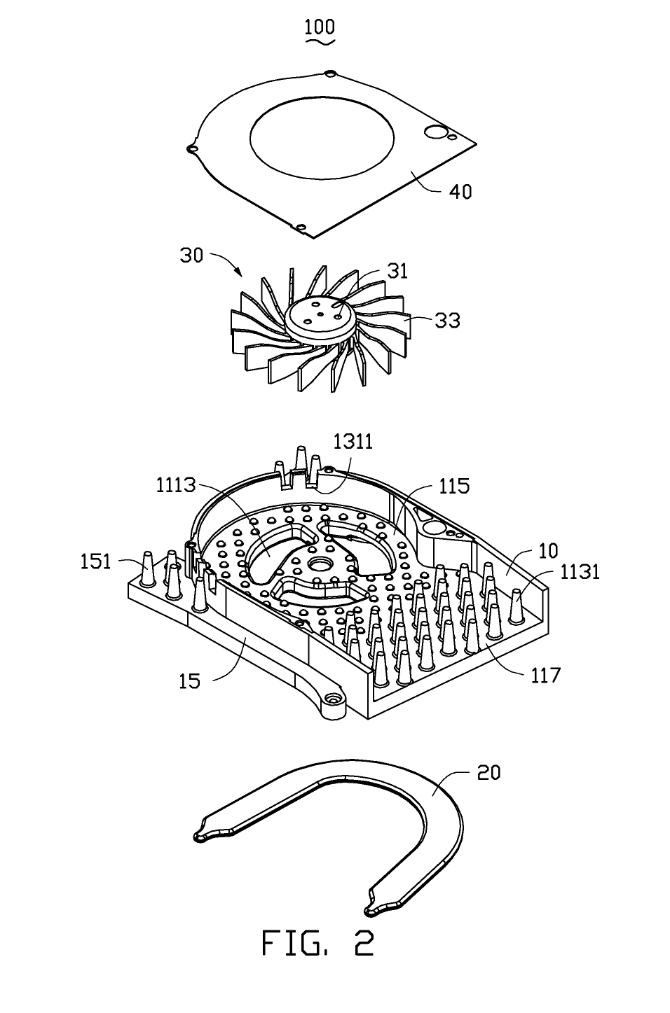

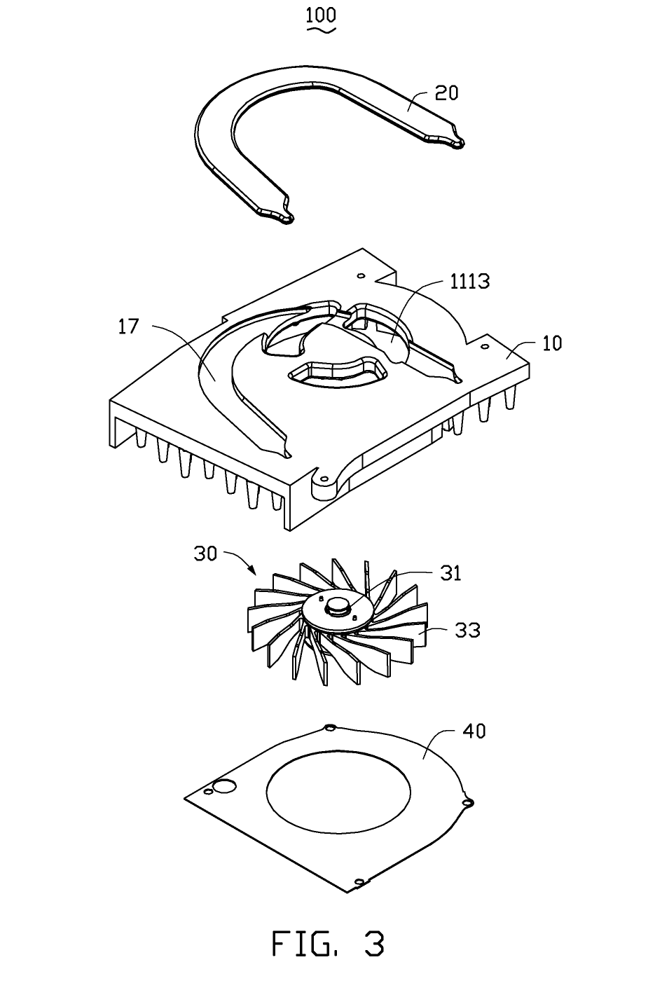

FIGS. 1 through 3 illustrate an embodiment of a fan module 100 employed in a notebook computer. The fan module 100 includes a base seat 10, a heat conducting tube 20 embedded in the base seat 10, a fan 30, and a covering plate 40. The heat conducting tube 20 and the fan 30 are assembled to opposite sides of the base seat 10. The covering plate 40 is secured to the base seat 10, and covers the fan 30. The fan module 100 can be employed in other electronic devices, such as assembled to a main processor box of a desktop computer.

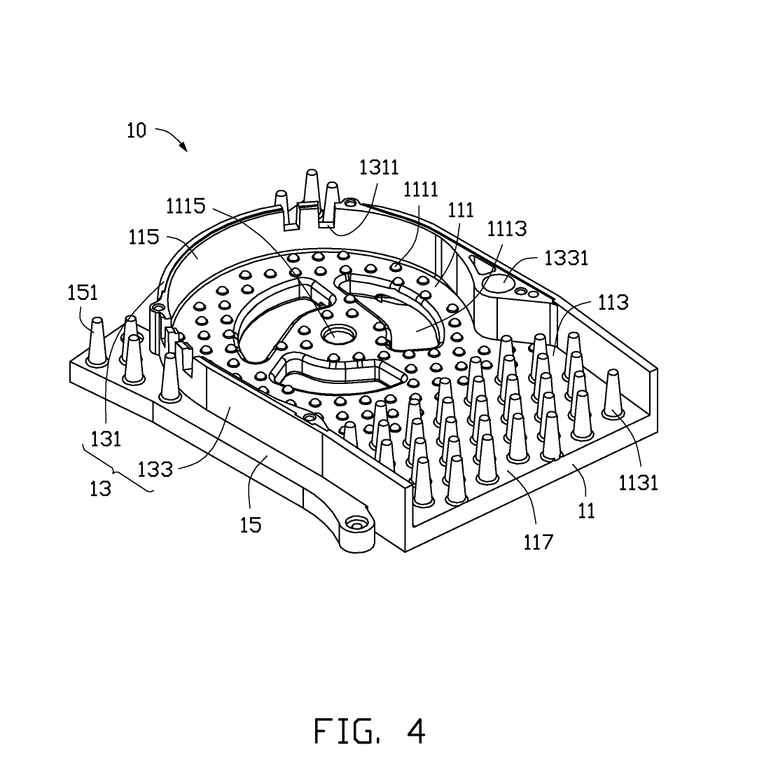

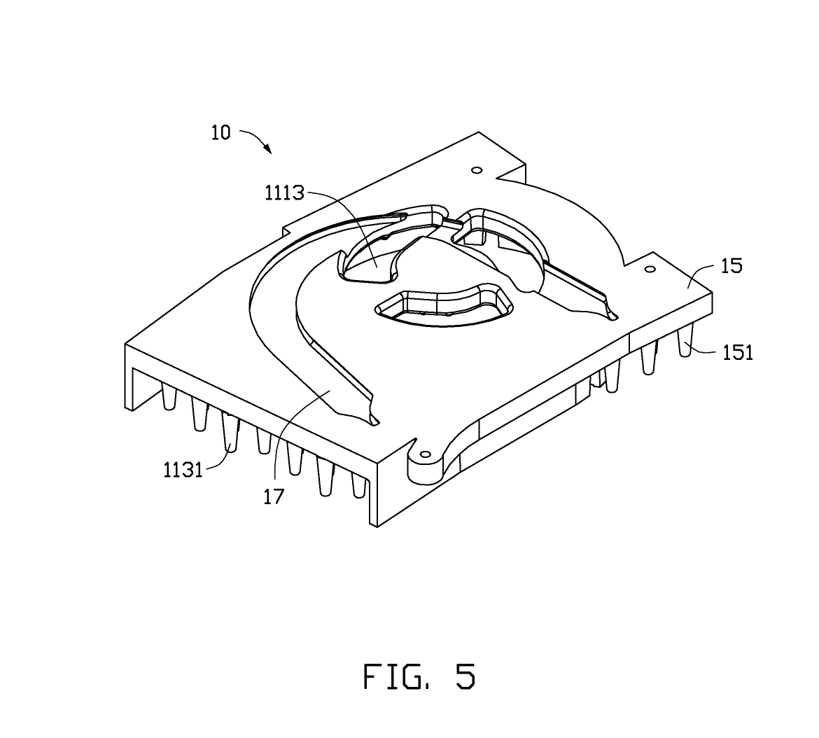

FIGS. 4 and 5 shows the base seat 10, which is integrally formed. The base seat 10 includes a bottom plate 11, a side wall 13 (see FIG. 4), and a pair of extending portions 15. The side wall 13 can have a “U” shape and divide the base seat 10 into two parts, an inner part within the side wall 13 and an outer part out of the sidewall 13. The bottom plate 11 includes a receiving portion 111 and a heat sink portion 113 connected to the receiving portion 111. The receiving portion 111 and the heat sink portion 113 are surrounded by the sidewall 13, and the pair of extending portions 15 are located at opposite sides of the sidewall 13 outside of the sidewall 13. The receiving portion 111 includes a plurality of heat conducting protrusions 1111, and defines three heat sink holes 1113 and a mounting hole 1115. Each heat conducting protrusion 1111 can have a hemi-spherical shape. An outer contour of the three heat sink holes 1113 defines a circle, and the mounting hole 1115 is defined in a center of the circle enclosed by the three heat sink holes 1113. The heat sink portion 113 comprises a plurality of first conducting posts 1131 uniformly arranged. Each first conducting post 1131 has a frustum shape, and a height of the first conducting post 1131 is greater than that of the heat conducting protrusion 1111. The pair of extending portions 15 is located at opposite sides of the bottom plate 11, and located at an outer side of the pair of sidewalls 13. Each extending portion 15 extends from the blocking plate 133 toward the connecting plate 131 and is equipped with a plurality of second conducting posts 151 at an end adjacent to the connecting plate 131. The plurality of second conducting posts 151 are arranged uniformly on the end of the extending portion 15. The number of the heat sink holes 1113 can be changed according to a requirement.

The sidewall 13 includes a connecting plate 131 in an arc shape and a pair of blocking plates 133 extending outwardly from opposite sides of the connecting plate 131. The connecting plate 131 surrounds the receiving portion 111 of the bottom plate 11 to define a mounting groove 115. The pair of blocking plates 133 blocks opposite sides of the heat sink portion 113, thereby defining a heat dissipation opening 117 communicating with the mounting groove 115. The connecting plate 131 defines a plurality of conducting cutouts 1311 divided into two groups. The two groups of conducting cutouts 1311 are respectively located at opposite ends of the connecting plate 131 corresponding to the plurality of second conducting posts 151. The blocking plate 133 has a straight strip shape and protrudes into an inner side of the heat dissipating opening 17 at a portion adjacent to the connecting plate 131, and defines a fixing hole 1311 substantially perpendicular to the bottom plate 11 on the portion.

The base seat 10 further defines an embedding groove 17 having a “U” shape at a side opposite to the sidewall 13. The embedding groove 17 communicates with two heat sink holes 1113. The base seat 10 is made of polymer thermal conductive materials, and composed of polyamide in about 40 percent weight ratio and nano-graphite in about 60 percent weight ratio. In an embodiment, the polyamide is polyamide 6. The heat conducting tube 20 is a vacuum heat conduction pipe having a “U” shape, and received in the embedding groove 17. In an embodiment, the heat conducting tube 20 is embedded in the embedding groove 17 by injection molding.

The fan 30 includes a vane wheel 31 and a plurality of vanes 33 extending from a periphery of the vane wheel 31. The plurality of vanes 33 extends radially outwardly from the vane wheel 31. The vane wheel 31 is rotatably mounted in the mounting hole 1115, and the plurality of the vanes 33 are located above the three heat sink holes 1113. The cover plate 40 seals a side of the mounting groove 115 opposite to the bottom plate 11, and assembled to the sidewall 13 via the fixing holes 1331.

In assembly, the heat conducting tube 20 is received in the embedding groove 17 of the base seat 10, and the fan 30 is rotatably mounted in the mounting hole 1115, then the covering plate 40 is secured to the base seat 10. When the fan module 100 is used, the fan 30 rotates and airflow is generated and blows from the mounting groove 115 toward the heat dissipation opening 17 and the conducting cutouts 1311, thereby exhausting heat from the first conducting posts 1131 of the heat sink portion 113 and the second conducting posts 151 of the extending portions 15.

The base seat 10 is made of polymer thermal conductive materials, and the first and second conducting posts 1131, 151 are distributed on the base seat 10. When the heat from the heat conducting tube 20 is conducted to the base seat 10, the fan 30 is capable of generating airflow to dissipate the heat from the first and second conducting posts 1131, 151, thereby enhancing a cooling efficiency. The first and second conducting posts 1131, 151 are distributed uniformly, thereby enhancing a heat exhausting homogeneity of the fan module 100. The fan 30 is directly assembled to the base seat 10, such that the base seat 10 functions as a bottom case of the fan 30. Furthermore, the heat conducting tube 20 is embedded in the embedding groove 17, such that a contact surface area between the heat conducting tube 20 and the base seat 10 is relatively large, thereby enhancing conduction efficiency.

While the present disclosure has been described with reference to particular embodiments, the description is illustrative of the disclosure and is not to be construed as limiting the disclosure. Therefore, those of ordinary skill in the art can make various modifications to the embodiments without departing from the true spirit and scope of the disclosure, as defined by the appended claims.

What is claimed is:

1. A fan module employed in an electronic device, comprising:
a base seat made of polymer thermal conductive materials, comprising:
a bottom plate and a “U” shaped sidewall extending from a side of the bottom plate, the bottom plate comprising a receiving portion and a heat sink portion connected to the receiving portion, the sidewall surrounding the receiving portion to form a mounting groove and surrounding opposite sides of the heat sink portion to form a heat dissipation opening communicating with the mounting groove, the heat sink portion comprising a plurality of first conducting posts, the sidewall defining a plurality of conducting cutouts, the bottom plate further comprising a plurality of second conducting posts outside of the sidewall and corresponding to the plurality of conducting cutouts;
a fan rotatably mounted on the receiving portion and received in the mounting groove;
a heat conducting tube embedded to a side of the base seat opposite to the fan; and
a covering plate secured to the sidewall and covering the fan to enable the fan generating air flow toward the heat dissipation hole and the plurality of conducting cutouts.

2. The fan module of claim 1, wherein the receiving portion comprises plurality of heat conducting protrusions, and defines a plurality of heat sink holes and a mounting hole, each heat conducting protrusion has a hemi-spherical shape, an outer contour of the plurality of heat sink holes defines a circle, the mounting hole is defined in a center of the circle enclosed by the plurality of heat sink holes, and the fan is rotatably mounted in the mounting hole.

3. The fan module of claim 2, wherein the base seat is integrally formed and defines an embedding groove opposite to the sidewall, the embedding groove communicates with at least one of the plurality of heat sink holes, and the heat conducting tube is embedded in the embedding groove.

4. The fan module of claim 1, wherein the base seat is composed of approximately 40% weight ratio of polyamide and approximately 60% weight ratio of nano-graphite, and the heat conducting tube is embedded in the base seat by injection molding method.

5. The fan module of claim 1, wherein the sidewall comprises a connecting plate having an arc shape and a pair of blocking plates extending outwardly from opposite sides of the connecting plate, the connecting plate surrounds the receiving portion to form the mounting groove, and the pair of blocking plates blocks opposite sides of the heat sink portion to forming the heat dissipation opening.

6. The fan module of claim 5, wherein the plurality of conducting cutouts is divided into two groups respectively defined on opposite ends of the connecting plate adjacent to the pair of blocking plates, each blocking plate protrudes into an inner side of the heat dissipating opening at a portion adjacent to the connecting plate, and defines a fixing hole substantially perpendicular to the bottom plate on the portion, and the covering plate is secured to the sidewall via the pair of fixing holes.

7. The fan module of claim 6, wherein the base seat further comprises a pair of extending portions at opposite sides of the bottom plate, the pair of extending portions is respectively located at an outer side of the sidewall, each extending portion extends from the blocking plate toward the connecting plate, and the plurality of second conducting posts of each extending plate is located at an end adjacent to the connecting plate and corresponds to one group of conducting cutouts.

8. The fan module of claim 2, wherein the fan comprises a vane wheel and a plurality of vanes extending from a periphery of the vane wheel, the plurality of vanes radially extending from the vane wheel outwardly, the vane wheel is rotatably mounted in the mounting hole, and the plurality of the vanes are located above the plurality of heat sink holes.

9. A base seat employed in a fan module, comprising:
a bottom plate;
a “U” shaped sidewall extending from a side of the bottom plate
wherein the sidewall and the bottom plate are made of polymer thermal conductive materials, the bottom plate comprises a receiving portion and a heat sink portion connected to the receiving portion, the sidewall surrounds the receiving portion to form a mounting groove and surrounds opposite sides of the heat sink portion to form a heat dissipation opening communicating with the mounting groove, the heat sink portion comprising a plurality of first conducting posts, the sidewall defines a plurality of conducting cutouts, and the bottom plate further comprises a plurality of second conducting posts outside of the sidewall and corresponding to the plurality of conducting cutouts.

10. The base seat of claim 9, wherein the receiving portion comprises plurality of heat conducting protrusions, and defines a plurality of heat sink holes and a mounting hole, each heat conducting protrusion has a hemi-spherical shape, an outer contour of the plurality of heat sink holes defines a circle, and the mounting hole is defined in a center of the circle enclosed by the plurality of heat sink holes.

11. The base seat of claim 10, wherein the base seat is integrally formed and defines an embedding groove opposite to the sidewall, and the embedding groove communicates with at least one of the plurality of heat sink holes.

12. The base seat of claim 9, wherein the base seat is composed of approximately 40% weight ratio of polyamide and approximately 60% weight ratio of nano-graphite.

13. The base seat of claim 9, wherein the sidewall comprises a connecting plate having an arc shape and a pair of blocking plates extending outwardly from opposite sides of the connecting plate, the connecting plate surrounds the receiving portion to form the mounting groove, and the pair of blocking plates blocks opposite sides of the heat sink portion to forming the heat dissipation opening.

14. The base seat of claim 13, wherein the plurality of conducting cutouts is divided into two groups respectively defined on opposite ends of the connecting plate adjacent to the pair of blocking plates, each blocking plate protrudes into an inner side of the heat dissipating opening at a portion adjacent to the connecting plate, and defines a fixing hole substantially perpendicular to the bottom plate on the portion.

15. The base seat of claim 14, wherein the base seat further comprises a pair of extending portions at opposite sides of the bottom plate, the pair of extending portions is respectively located at an outer side of the sidewall, each extending portion extends from the blocking plate toward the connecting plate, and the plurality of second conducting posts of each extending plate is located at an end adjacent to the connecting plate and corresponds to one group of conducting cutouts.
